(19) United States
(12) Patent Application Publication
(10) Pub. No.: US 2026/0173411 A1
(43) Pub. Date: Jun. 18, 2026

(54) SEMICONDUCTOR DEVICE

(71) Applicant: Renesas Electronics Corporation, Tokyo (JP)

(72) Inventors: Yasutaka NAKASHIBA, Tokyo (JP); Takayuki IGARASHI, Tokyo (JP)

(21) Appl. No.: 19/416,692

(22) Filed: Dec. 11, 2025

(30) Foreign Application Priority Data
Dec. 12, 2024 (JP) 2024-217557

(51) Int. Cl. H10D 1/20; H10D 1/00

(52) U.S. Cl. CPC H10D 1/20; H10D 1/01

(57) ABSTRACT

A semiconductor device includes: a semiconductor substrate having an upper surface; and wiring layers and insulating layers alternately stacked on the upper surface. The insulating layers include: a first insulating layer located between the first wiring layer located at the lowest layer among the wiring layers in cross-sectional view and the semiconductor substrate; and a second insulating layer located between a second wiring layer located at one layer above the first wiring layer among the wiring layers in cross-sectional view and the first wiring layer. The first wiring layer includes: a first coil; a first lead-out wiring electrically connected to the outermost peripheral portion of the first coil; and a second lead-out wiring electrically connected to the innermost peripheral portion of the first coil. The wiring layer located above the first wiring layer among the wiring layers in cross-sectional view includes a second coil overlapping the first coil.

### CROSS-REFERENCE TO RELATED APPLICATIONS

The disclosure of Japanese Patent Application No. 2024-217557 filed on Dec. 12, 2024, including the specification, drawings and abstract is incorporated herein by reference in its entirety.

### BACKGROUND

This disclosure relates to a semiconductor device.

There is a disclosed technique listed below.

[Patent Document 1] Japanese Unexamined Patent Application Publication No. 2024-44675

The semiconductor device disclosed in Patent Document 1 includes a semiconductor substrate, a first insulating layer formed on the semiconductor substrate, a first coil formed on the first insulating layer, a second insulating layer formed to cover the first coil, and a second coil formed on the second insulating layer so as to overlap the first coil in a plan view. In the semiconductor device disclosed in Patent Document 1, signal transmission is performed between the first coil and the second coil.

### SUMMARY

In the semiconductor device disclosed in Patent Document 1, there is a room for improvement in suppressing common mode noise superimposed on the signal transmitted between the first coil and the second coil. Other problems and novel features will become apparent from the description herein and from the accompanying drawings.

The semiconductor device of the present disclosure includes: a semiconductor substrate having an upper surface; and a plurality of wiring layers and a plurality of insulating layers alternately stacked on the upper surface of the semiconductor substrate. The plurality of insulating layers includes: a first insulating layer located between the first wiring layer, which is located at the lowermost layer among the plurality of wiring layers in cross-sectional view, and the semiconductor substrate; and a second insulating layer located between a second wiring layer, which is located at one layer above the first wiring layer among the plurality of wiring layers in cross-sectional view, and the first wiring layer. The first wiring layer includes: a first coil; a first lead-out wiring electrically connected to the outermost peripheral portion of the first coil; and a second lead-out wiring electrically connected to the innermost peripheral portion of the first coil. A wiring layer, which is located above the first wiring layer among the plurality of wiring layers in cross-sectional view, includes a second coil overlapping the first coil. Each of the plurality of wiring layers includes: a first electrode electrically connected to the first lead-out wiring; and a second electrode electrically connected to the second lead-out wiring. The first electrode and the second electrode both provided in a third wiring layer, which is located at the uppermost layer among the plurality of wiring layers in cross-sectional view, form a first pad and a second pad, respectively. The first electrode provided in one of two wiring layers, which are adjacent to each other, among the plurality of wiring layers and the second electrode provided in the other of the two wiring layers, which are adjacent to each other, among the plurality of wiring layers overlap each other.

According to the semiconductor device of this disclosure, it is possible to suppress common mode noise superimposed on the signal transmitted between the first coil and the second coil.

### BRIEF DESCRIPTION OF THE DRAWINGS

FIG. 1 is a block diagram of a semiconductor device DEV1 according to the first embodiment.

FIG. 2 is an explanatory diagram showing an example of signal transmission from semiconductor chip CHP1 to semiconductor chip CHP2.

FIG. 3 is a first plan view of semiconductor chip CHP3 according to the first embodiment.

FIG. 4 is a second plan view of semiconductor chip CHP3 according to the first embodiment.

FIG. 5 is a third plan view of semiconductor chip CHP3 according to the first embodiment.

FIG. 6 is a cross-sectional view of semiconductor chip CHP3 along VI-VI in FIG. 5.

FIG. 7 is a cross-sectional view of semiconductor chip CHP3 along VII-VII in FIG. 5.

FIG. 8 is a manufacturing process diagram of semiconductor chip CHP3 according to the first embodiment.

FIG. 9 is a cross-sectional view explaining the impurity diffusion layer formation process S2.

FIG. 10 is a cross-sectional view explaining the interlayer insulating film formation process S3.

FIG. 11 is a cross-sectional view explaining the wiring layer formation process S4.

FIG. 12 is a cross-sectional view explaining the interlayer insulating film formation process S5.

FIG. 13 is a cross-sectional view explaining the via plug formation process S6.

FIG. 14 is a cross-sectional view explaining the wiring layer formation process S7.

FIG. 15 is a cross-sectional view of semiconductor chip CHP4 according to a comparative example.

FIG. 16 is a cross-sectional view of semiconductor chip CHP3 in semiconductor device DEV2 according to the second embodiment.

FIG. 17 is a first plan view of semiconductor chip CHP3 in semiconductor device DEV3 according to the third embodiment.

FIG. 18 is a second plan view of semiconductor chip CHP3 in semiconductor device DEV3 according to the third embodiment.

FIG. 19 is a third plan view of semiconductor chip CHP3 in semiconductor device DEV3 according to the third embodiment.

FIG. 20 is a fourth plan view of semiconductor chip CHP3 in semiconductor device DEV3 according to the third embodiment.

FIG. 21 is a fifth plan view of semiconductor chip CHP3 in semiconductor device DEV3 according to the third embodiment.

FIG. 22 is a plan view of semiconductor device CH3 in semiconductor device DEV4 according to the fourth embodiment.

FIG. 23A is the first cross-sectional view of semiconductor chip CHP3 along XXIIIA-XXIIIA in FIG. 22 in semiconductor device DEV4 according to the fourth embodiment.

FIG. 23B is a second cross-sectional view of semiconductor chip CHP3 along XXIIIB-XXIIIB in FIG. 22 in semiconductor device DEV4 according to the fourth embodiment.

FIG. 24A is a third cross-sectional view of semiconductor chip CHP3 along XXIVA-XXIVA in FIG. 22 in semiconductor device DEV4 according to the fourth embodiment.

FIG. 24B is a fourth cross-sectional view of semiconductor chip CHP3 along XXIVB-XXIVB in FIG. 22 in semiconductor device DEV4 according to the fourth embodiment.

FIG. 25 is a plan view of semiconductor chip CHP3 in semiconductor device DEV1 according to the first modified example.

FIG. 26 is a cross-sectional view of semiconductor chip CHP3 in semiconductor device DEV1 according to the first modified example.

FIG. 27 is a plan view of semiconductor chip CHP3 in semiconductor device DEV1 according to the second modified example.

### DETAILED DESCRIPTION

The details of the embodiments of the present disclosure will be described with reference to the drawings. In the following drawings, the same or equivalent parts are denoted by the same reference numerals, and redundant descriptions are not repeated.

### First Embodiment

The semiconductor device DEV1 according to the first embodiment will be described.

### <Outline Of Semiconductor Device DEV1>

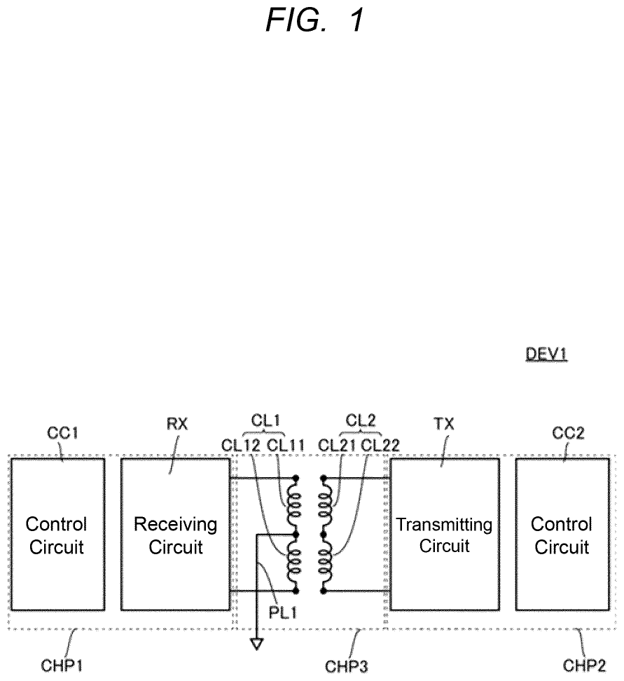

As shown in FIG. 1, the semiconductor device DEV1 includes a semiconductor chip CHP1 and a semiconductor chip CHP2. The semiconductor chip CHP1 includes a receiving circuit RX and a control circuit CC1. The semiconductor chip CHP2 includes a transmitting circuit TX and a control circuit CC2. The semiconductor device DEV1 further includes a semiconductor chip CHP3. The semiconductor chip CHP3 includes a coil CL1, a coil CL2, and a lead-out wiring PL1.

The coil CL1 includes a coil CL11 and a coil CL12. One end portion of the coil CL11 is electrically connected to the receiving circuit RX, and the other end portion of the coil CL11 is connected to one end portion of the coil CL12. The other end portion of the coil CL12 is electrically connected to the receiving circuit RX. The coil CL2 includes a coil CL21 and a coil CL22. One end portion of the coil CL21 is electrically connected to the transmitting circuit TX, and the other end portion of the coil CL21 is connected to one end portion of the coil CL22. The other end portion of the coil CL22 is electrically connected to the transmitting circuit TX.

The lead-out wiring PL1 is connected to the other end portion (outermost peripheral portion) of the coil CL11 and one end portion (outermost peripheral portion) of the coil CL12. The control circuit CC1 is electrically connected to the receiving circuit RX. The control circuit CC2 is electrically connected to the transmitting circuit TX.

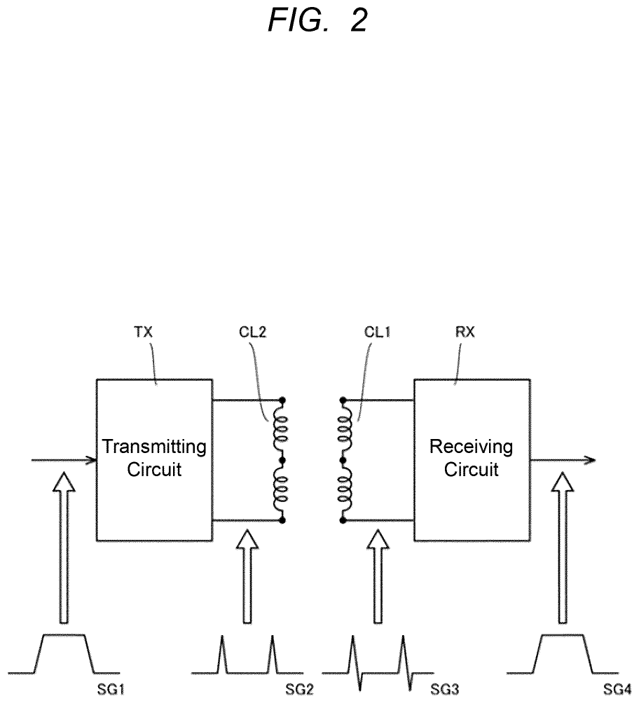

As shown in FIG. 2, the control circuit CC2 outputs a signal SG1 to the transmitting circuit TX. The signal SG1 is a square wave. The transmitting circuit TX modulates the signal SG1 into a signal SG2 and sends the signal SG2 to the coil CL2. When the signal SG2 flows through the coil CL2, a signal SG3 corresponding to the signal SG2 flows through the coil CL1 due to induced electromotive force. The receiving circuit RX amplifies the signal SG3 and demodulates the amplified signal SG3 into a signal SG4. The receiving circuit RX outputs the signal SG4 to the control circuit CC1.

### <Configuration Of Semiconductor Chip CHP3>

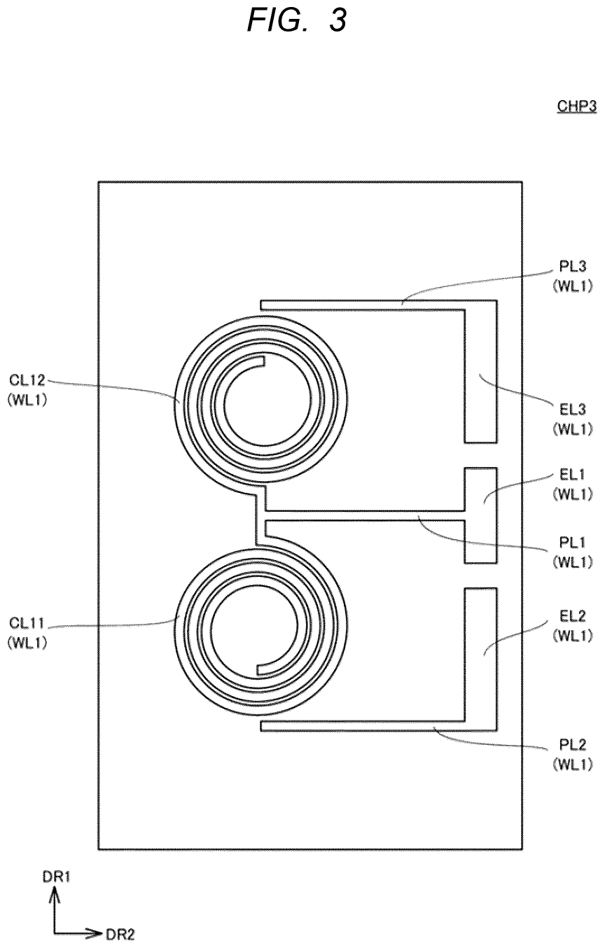

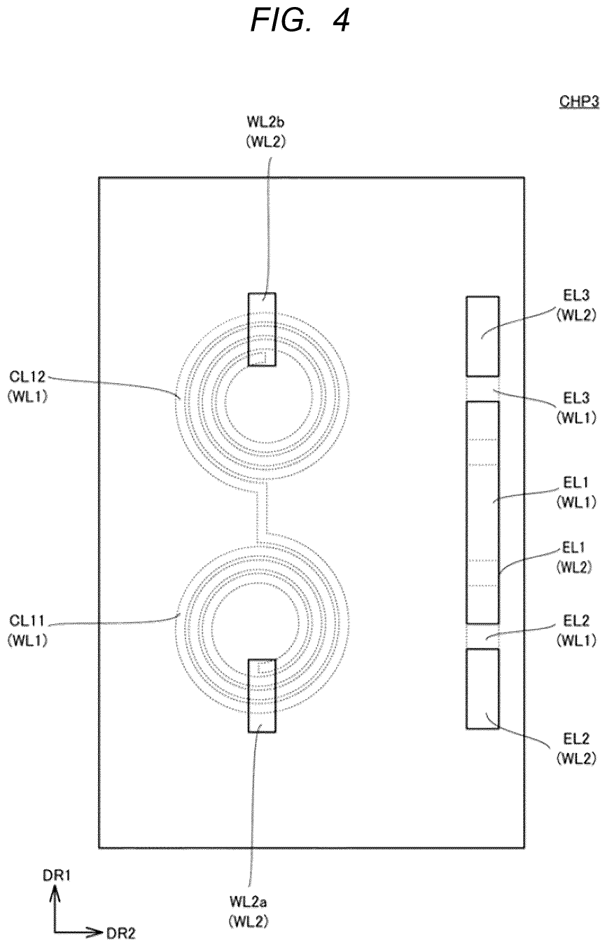

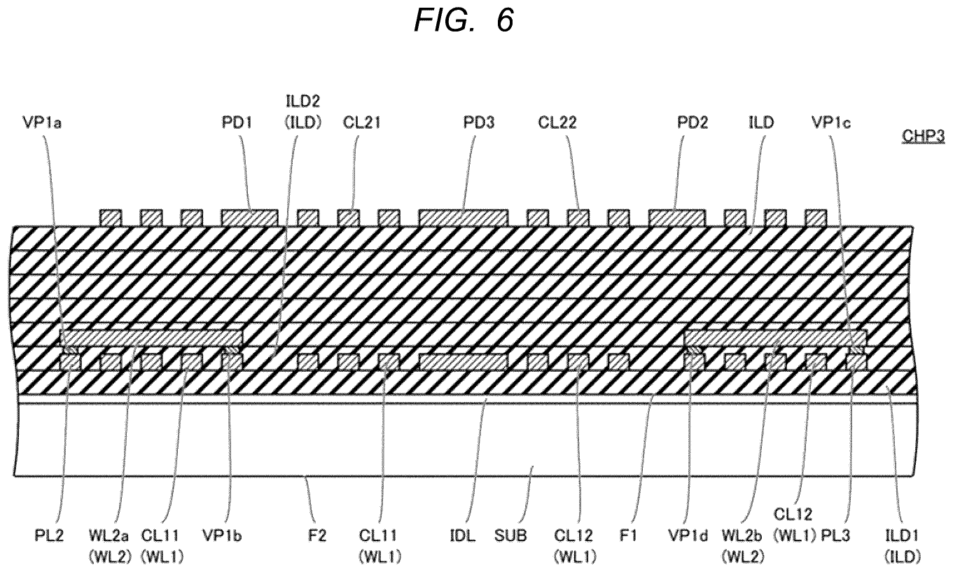

As shown in FIGS. 3, 4, 5, 6, and 7, the semiconductor chip CHP3 includes a semiconductor substrate SUB, a plurality of wiring layers WL, and a plurality of interlayer insulating films ILD.

The semiconductor substrate SUB has an upper surface F1 and a lower surface F2 located on the opposite side of the upper surface F1. The semiconductor substrate SUB is formed of, for example, single-crystal silicon. The conductivity type of the semiconductor substrate SUB is, for example, p-type. The semiconductor substrate SUB may have an impurity diffusion layer IDL. The conductivity type of the impurity diffusion layer IDL is, for example, p-type. The impurity concentration in the impurity diffusion layer IDL is higher than the impurity concentration in the semiconductor substrate SUB outside the impurity diffusion layer IDL. The impurity diffusion layer IDL is formed on the upper surface F1 within the semiconductor substrate SUB.

Each of the plurality of wiring layers WL is formed of, for example, aluminum or an aluminum alloy. The plurality of wiring layers WL is laminated on the upper surface F1. Each of the plurality of interlayer insulating films ILD is formed of, for example, silicon oxide. Each of the plurality of interlayer insulating films ILD is formed between one (wiring layer WL1) located at the lowermost layer of the plurality of wiring layers WL and the upper surface F1, and between two adjacent ones of the plurality of wiring layers WL. From another perspective, except for one located at the uppermost layer of the plurality of wiring layers WL, one of the pluralities of wiring layers WL is formed on one interlayer insulating film ILD and covered by another interlayer insulating film ILD. The interlayer insulating film ILD located at the lowermost layer of the plurality of interlayer insulating films ILD is referred to as interlayer insulating film ILD1. The interlayer insulating film ILD1 is located between the semiconductor substrate SUB and the wiring layer WL1. Also, the interlayer insulating film ILD located on the wiring layer WL1 among the plurality of interlayer insulating films ILD is referred to as interlayer insulating film ILD2.

Also, one of the pluralities of wiring layers WL, for example, one located at the lowermost layer of the plurality of wiring layers WL (wiring layer WL1), includes a coil CL1, a lead-out wiring PL1, a lead-out wiring PL2, and a lead-out wiring PL3. The coil CL1 includes a coil CL11 and a coil CL12. The coil CL11 and the coil CL12 are arranged side by side in the first direction DR1 in plan view.

The coil CL11 is wound in a spiral shape in plan view. More specifically, the coil CL11 is wound counterclockwise from one end located at the innermost periphery to the other end located at the outermost periphery in plan view. The coil CL12 is wound in a spiral shape in plan view. More specifically, the coil CL12 is wound clockwise from one end portion located at the outermost peripheral portion to the other end portion located at the innermost peripheral portion in plan view.

Each of the lead-out wiring PL1, the lead-out wiring PL2, and the lead-out wiring PL3 extends in the second direction DR2 perpendicular to the first direction DR1 in plan view. One end portion of the lead-out wiring PL1 is connected to the other end portion (outermost peripheral portion) of the coil CL11 and one end portion (outermost peripheral portion) of the coil CL12. One end portion of the lead-out wiring PL2 is located next to the coil CL11. One end portion of the lead-out wiring PL3 is located next to the coil CL12. The lead-out wiring PL1 is a center tap wiring that supplies a ground potential to the other end portion of the coil CL11 and one end portion of the coil CL12. Each of the lead-out wiring PL2 and the lead-out wiring PL3 is a signal wiring through which a signal transmitted and received between the semiconductor chip CHP1 and the semiconductor chip CHP2 flows.

One located on the wiring layer WL1 among the plurality of wiring layers WL, namely the wiring layer WL2, includes a wiring WL2a and a wiring WL2b. Each of the wiring WL2a and the wiring WL2b extends in the first direction DR1. One end portion and the other end portion of the wiring WL2a overlap with one end portion (innermost peripheral portion) of the coil CL11 and one end portion of the lead-out wiring PL2, respectively, in plan view. One end portion and the other end portion of the wiring WL2b overlap with the other end portion (innermost peripheral portion) of the coil CL12 and one end portion of the lead-out wiring PL3, respectively, in plan view.

The semiconductor chip CHP3 includes a via plug VP1a, a via plug VP1b, a via plug VP1c, and a via plug VP1d. The via plugs VP1a to VP1d are formed in the interlayer insulating film ILD covering the wiring layer WL1. Each of the via plugs VP1a to VP1d are formed of, for example, tungsten. The via plug VP1a connects one end portion of the wiring WL2a and one end portion of the coil CL11, and the via plug VP1b connects the other end portion of the wiring WL2a and one end portion of the lead-out wiring PL2. The via plug VP1c connects one end portion of the wiring WL2b and the other end portion of the coil CL12, and the via plug VP1d connects the other end portion of the wiring WL2b and one end portion of the lead-out wiring PL3.

One located at the uppermost layer of the plurality of wiring layers WL, namely the wiring layer WL3, includes a coil CL2, a pad PD1, a pad PD2, a pad PD3, and a guard ring GR. The coil CL2 includes a coil CL21 and a coil CL22. The coil CL21 and the coil CL22 are arranged side by side in the first direction DR1. In plan view, the coil CL2 overlaps with the coil CL1. More specifically, in plan view, the coil CL21 overlaps with the coil CL11, and the coil CL22 overlaps with the coil CL12.

The coil CL21 is wound in a spiral shape in plan view. More specifically, the coil CL21 is wound counterclockwise from one end located at the innermost periphery to the other end located at the outermost periphery in plan view. The coil CL22 is wound in a spiral shape in plan view. More specifically, the coil CL22 is wound clockwise from one end located at the outermost periphery to the other end located at the innermost periphery in plan view. The pad PD1 is connected to one end portion of the coil CL21. The pad PD2 is connected to the other end portion of the coil CL22. The pad PD3 connects the other end portion of the coil CL21 and one end portion of the coil CL22. The guard ring GR surrounds the coil CL2 (coil CL21, coil CL22) in plan view. Opening portions OP1 and OP2 are formed in the guard ring GR. The coil CL2 is located at an inside of the opening portion OP1 in plan view. The semiconductor chip CHP3 is electrically connected to the semiconductor chip CHP2 (receiving circuit RX) at the pad PD1 and the pad PD2.

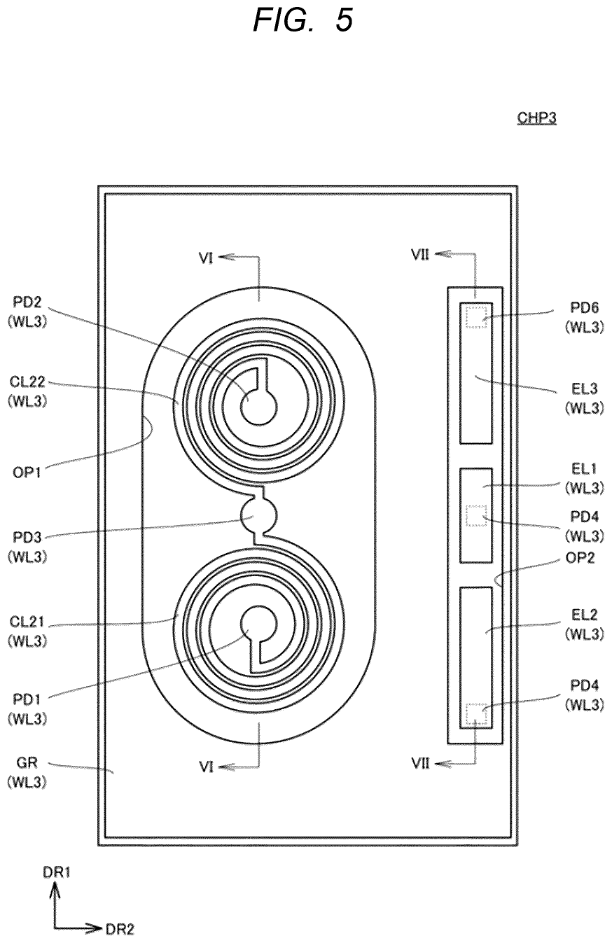

Each of the plurality of wiring layers WL includes an electrode EL1, an electrode EL2, and an electrode EL3. Although not shown, a passivation film is formed on one located at the uppermost layer of the plurality of interlayer insulating films ILD so as to cover the wiring layer WL3. Portions of the electrodes EL1, EL2, and EL3 of the wiring layer WL3 exposed from opening portions formed in the passivation film (see the dotted lines in FIG. 5) form the pads PD4, PD5, and PD6, respectively. The pads PD4, PD5, and PD6 are located at an inside of the opening portion OP2 in plain view. The pads PD4, PD5, and PD6 are arranged such that the pad PD4 is located between the pad PD5 and the pad PD6 in the first direction DR1. The ground potential is applied to pad PD4. The semiconductor chip CHP3 is electrically connected to the semiconductor chip CHP1 (transmission circuit TX) at pad PD5 and pad PD6.

One of the two adjacent electrodes EL1 among the multiple wiring layers WL and the other of the two adjacent electrodes EL2 among the multiple wiring layers WL overlapped each other in a plan view. In the example shown in FIGS. 3 to 7, in the area located between pad PD4 and pad PD5 in a plan view, one of the two adjacent electrodes EL1 among the multiple wiring layers WL and the other of the two adjacent electrodes EL2 among the multiple wiring layers WL overlap each other in a plan view. Also, in this example, in the area located between pad PD4 and pad PD6 in a plan view, one of the two adjacent electrodes EL1 among the multiple wiring layers WL and the other of the two adjacent electrodes EL3 among the multiple wiring layers WL overlaps each other in a plan view. Hereinafter, the area located between pad PD4 and pad PD5 in a plan view and the area located between pad PD4 and pad PD6 in a plan view may be referred to as the first region.

Furthermore, the semiconductor chip CHP3 includes multiple via plugs VP2a, multiple via plugs VP2b, and multiple via plugs VP2c. The via plugs VP2a, VP2b, and VP2c are formed inside each of the multiple interlayers insulating films ILD located above the bottommost layer. The via plugs VP2a, VP2b, and VP2c are formed, for example, of tungsten. Two adjacent electrodes EL1 among the multiple wiring layers WL are connected to each other by the via plug VP2a. Two adjacent electrodes EL2 among the multiple wiring layers WL are connected to each other by the via plug VP2b. Two adjacent electrodes, EL3 among the multiple wiring layers WL are connected to each other by the via plug VP2c.

The electrode EL1 of the wiring layer WL1 is connected to the other end portion of the lead-out wiring PL1. The electrodes EL2 and EL3 of the wiring layer WL1 are connected to the other end portion of the lead-out wiring PL2 and the other end portion of the lead-out wiring PL3, respectively.

### <Method Of Manufacturing Semiconductor Chip CHP3>

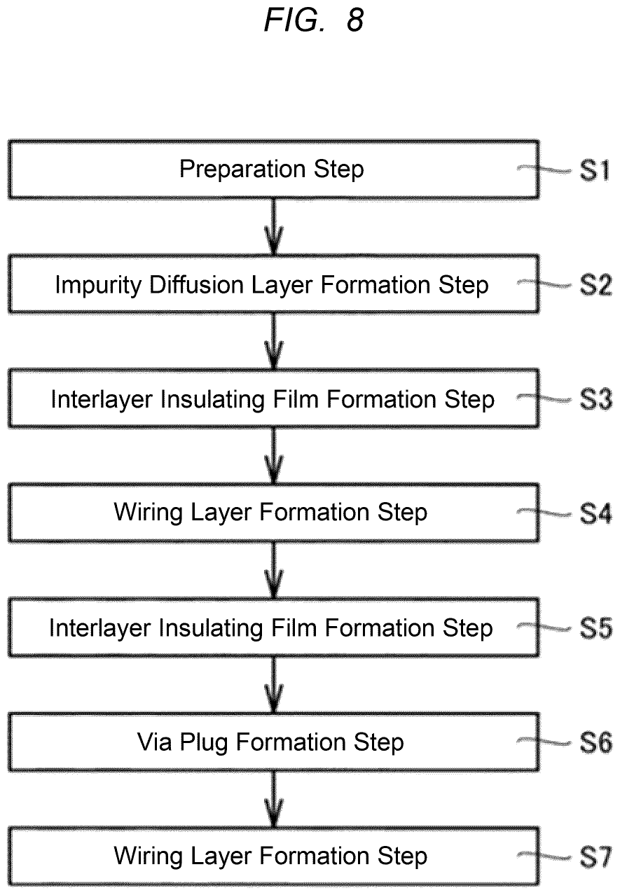

As shown in FIG. 8, the manufacturing method of the semiconductor chip CHP3 includes a preparation step S1, an impurity diffusion layer formation step S2, an interlayer insulating film formation step S3, a wiring layer formation step S4, an interlayer insulating film formation step S5, a via plug formation step S6, and a wiring layer formation step S7.

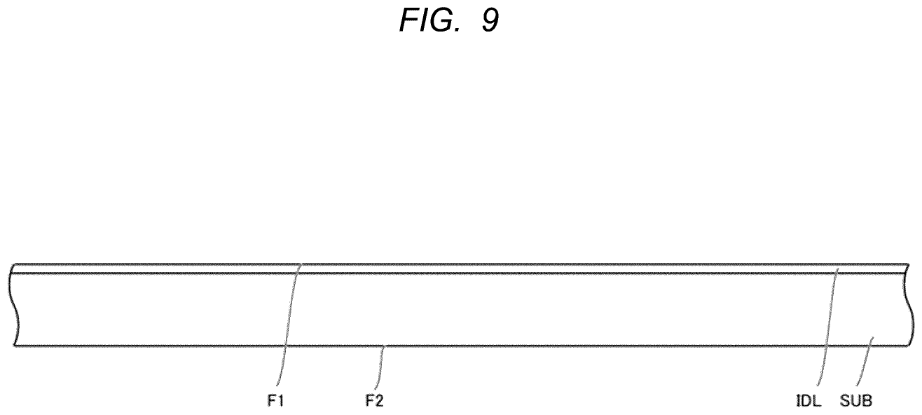

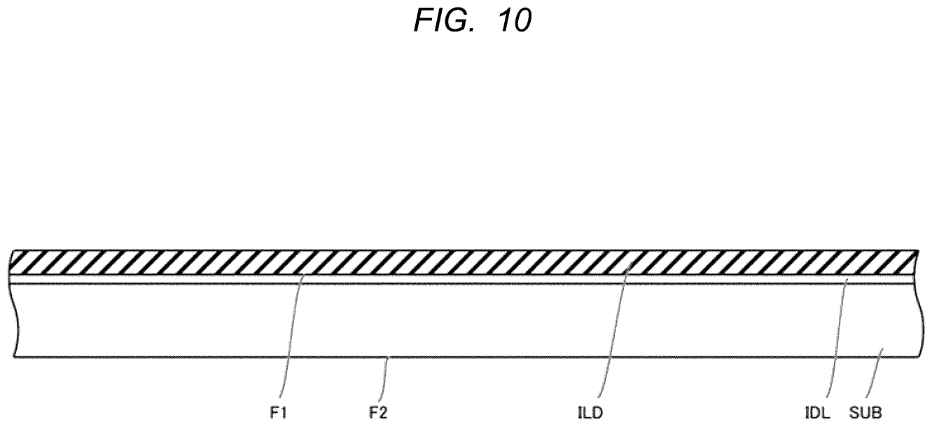

In the preparation step S1, the semiconductor substrate SUB is prepared. As shown in FIG. 9, in the impurity diffusion layer formation step S2, for example, by performing ion implantation on the upper surface F1, an impurity diffusion layer IDL is formed on the upper surface F1 within the semiconductor substrate SUB. As shown in FIG. 10, in the interlayer insulating film formation step S3, for example, by performing CVD (Chemical Vapor Deposition), one of the lowermost interlayers insulating films ILD (interlayer insulating film ILD1) is formed on the upper surface F1.

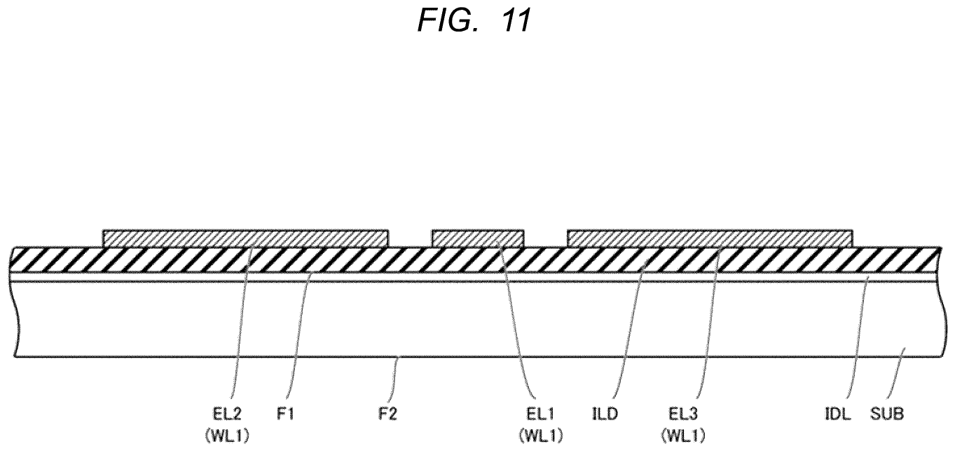

As shown in FIG. 11, in the wiring layer formation step S4, a wiring layer WL (wiring layer WL1) is formed on one of the lowermost interlayers insulating films ILD. In the wiring layer formation step S4, firstly, for example, by performing sputtering, the material of the wiring layer WL is deposited on one of the lowermost interlayers insulating films ILD. Secondly, a resist pattern with an opening portion is formed on the material of the wiring layer WL. The resist pattern is formed by patterning the photoresist applied on the material of the wiring layer WL using photolithography. Thirdly, by dry etching the material of the wiring layer WL through the opening portion of the resist pattern, the material of the wiring layer WL is patterned, and the wiring layer WL is formed.

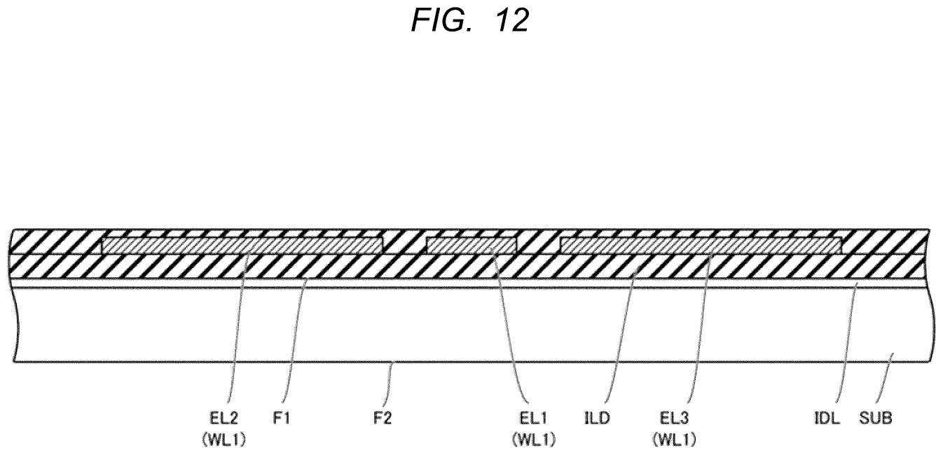

As shown in FIG. 12, in the interlayer insulating film formation step S5, an interlayer insulating film ILD (interlayer insulating film ILD2) is formed so as to cover the wiring layer WL (wiring layer WL1). In the interlayer insulating film formation step S5, firstly, for example, by performing CVD, the material of the interlayer insulating film ILD is formed to cover the wiring layer WL. Secondly, for example, by performing CMP (Chemical Mechanical Polishing), the upper surface of the material of the interlayer insulating film ILD is flattened, and the interlayer insulating film ILD is formed.

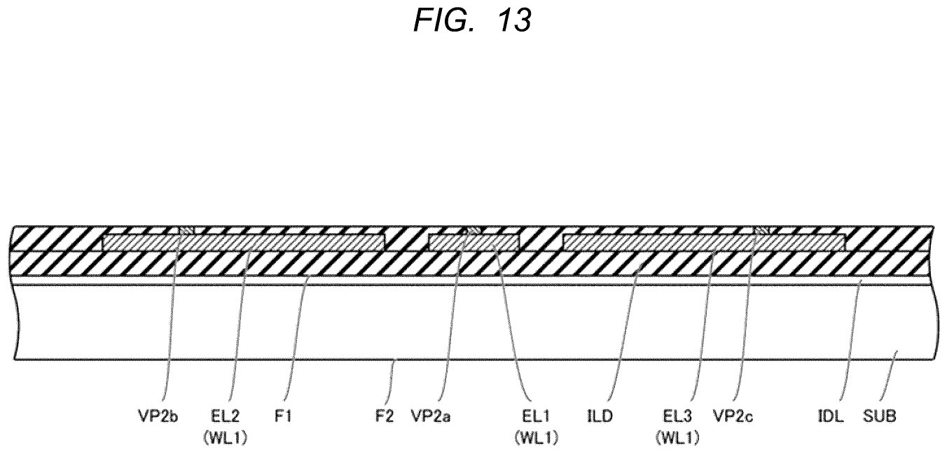

As shown in FIG. 13, in the via plug formation step S6, via plugs VP2a, VP2b, and VP2c are formed within the interlayer insulating film ILD. In the via plug formation step S6, a resist pattern with an opening portion is formed on the interlayer insulating film ILD. Secondly, by performing dry etching on the interlayer insulating film ILD through the opening portion of the resist pattern, via holes are formed within the interlayer insulating film ILD. Thirdly, for example, by performing CVD, the material of via plugs such as VP2a is formed within the via holes and on the interlayer insulating film ILD. Fourthly, for example, by performing CMP, the material of via plugs such as VP1a formed outside the via holes is removed, and via plugs VP2a, VP2b, and VP2c are formed. Although not shown, at this time, via plugs VP1a to VP1d are also formed in the same process.

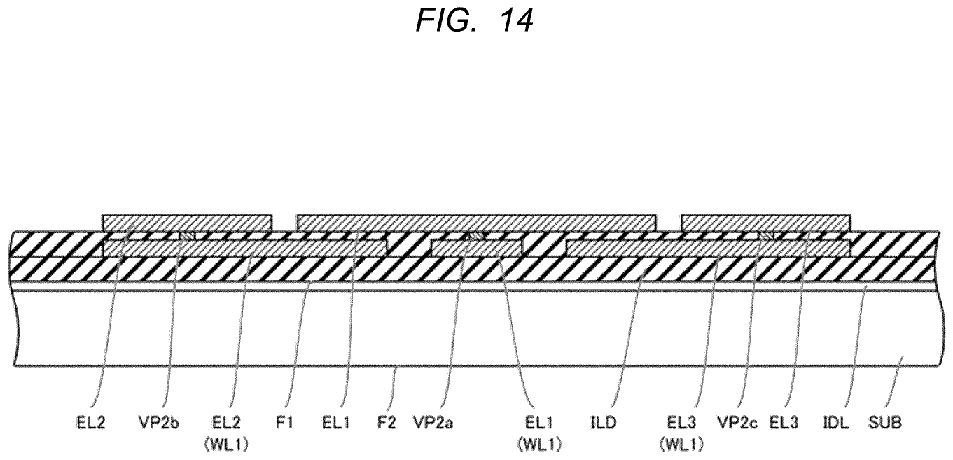

As shown in FIG. 14, in the wiring layer formation step S7, a wiring layer WL (wiring layer WL2) is formed on the interlayer insulating film ILD (interlayer insulating film ILD2) through a process similar to the wiring layer formation step S4. Thereafter, by sequentially repeating the interlayer insulating film formation step S5, the via plug formation step S6, and the wiring layer formation step S7, upper interlayer insulating films ILD, via plugs VP2a, VP2b, VP2c, and wiring layers WL are formed, and the structure of the semiconductor chip CHP3 shown in FIGS. 3 to 7 is obtained.

### <Effect Of Semiconductor Device DEV1>

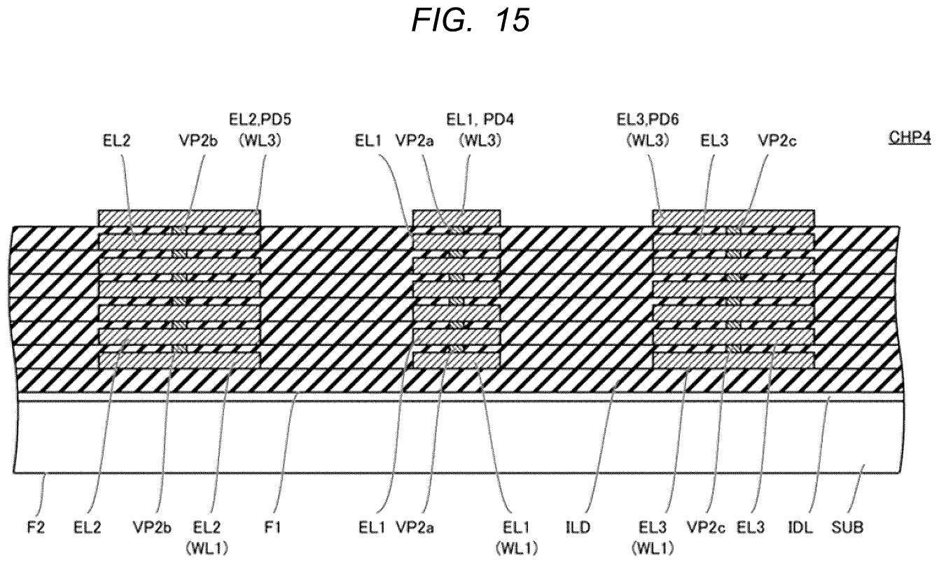

When a signal is transmitted between coil CL1 and coil CL2, common mode noise may be superimposed on the signal. As shown in FIG. 15, in the semiconductor chip CHP4 according to the comparative example, one of the adjacent two electrodes EL1 of the multiple wiring layers WL and the other of the adjacent two electrodes EL2 (electrode EL3) of the multiple wiring layers WL do not overlap each other in a plan view. Therefore, in the semiconductor chip CHP4, although a capacitor is formed between the adjacent electrodes EL1 and EL2 (electrode EL3) within the same wiring layer WL, the capacitance of the capacitor is small and does not significantly contribute to the suppression of common mode noise.

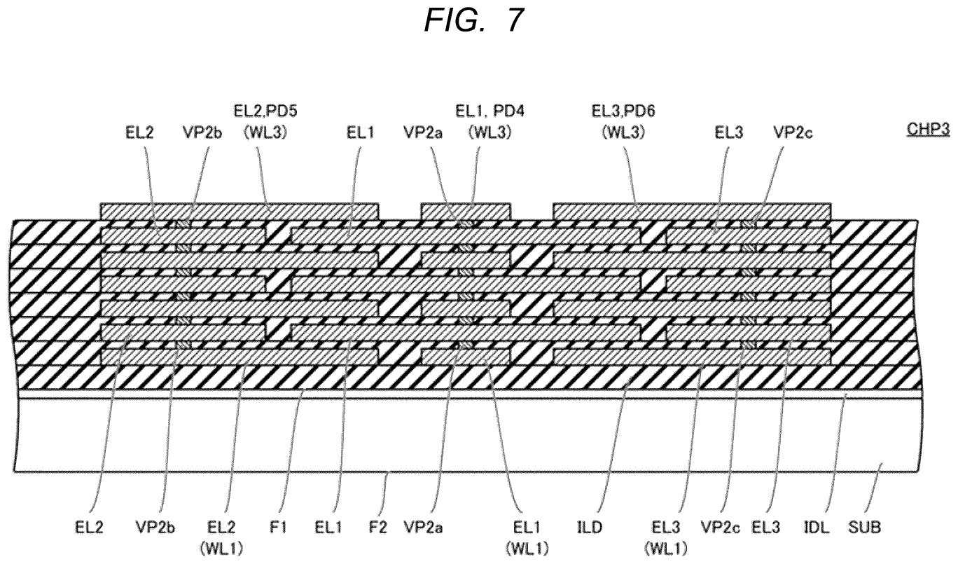

In contrast, as shown in FIG. 7, in the semiconductor chip CHP3 according to the first embodiment, one of the adjacent two electrodes EL1 of the multiple wiring layers WL and the other of the adjacent two electrodes EL2 (electrode EL3) of the multiple wiring layers WL overlap each other in a plan view. Therefore, in the semiconductor chip CHP3, the capacitance of the capacitor formed between the electrodes EL1 and EL2 (electrode EL3) becomes large. Thus, according to the semiconductor device DEV1 having the semiconductor chip CHP3, it is possible to suppress the superimposition of common mode noise on the signal transmitted between coil CL1 and coil CL2. In the semiconductor chip CHP3, since such a capacitor can be formed by utilizing dead space, it does not lead to an increase in chip area.

### Second Embodiment

The semiconductor device DEV2 according to the second embodiment will be described. Here, the differences from the semiconductor device DEV1 will be mainly described, and repetitive descriptions will not be repeated.

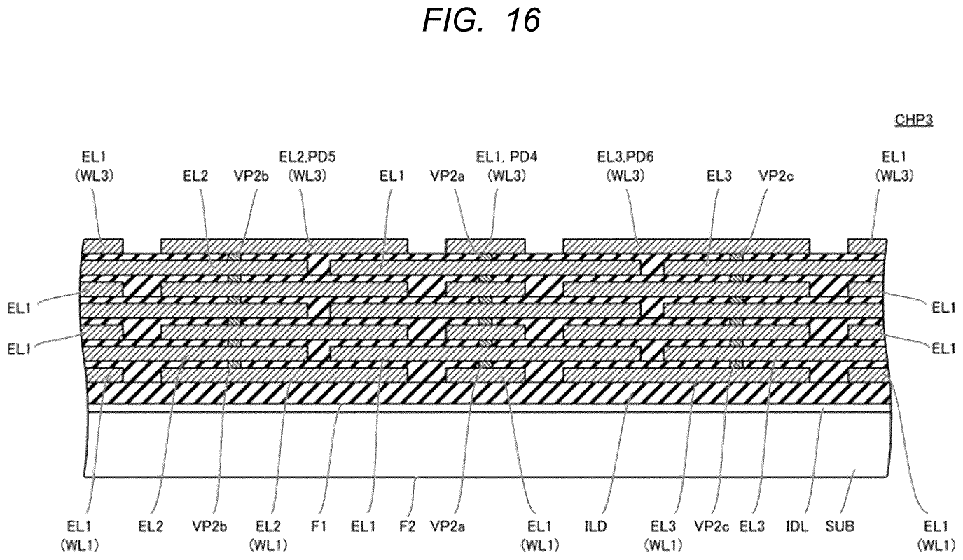

FIG. 16 shows a cross-section of the semiconductor chip CHP3 of the semiconductor device DEV2 at a position corresponding to VII-VII in FIG. 5. As shown in FIG. 16, in the semiconductor chip CHP3 of the semiconductor device DEV2, one of the adjacent two electrodes EL1 of the multiple wiring layers WL and the other of the adjacent two electrodes EL2 (electrode EL3) of the multiple wiring layers WL overlap each other in a region (second region) located at an inside of the opening portion OP2 and outside the first region in plan view, in addition to the first region. Therefore, in the semiconductor chip CHP3 of the semiconductor device DEV2, compared to the semiconductor chip CHP3 of the semiconductor device DEV1, the overlap between the electrodes EL1 and EL2 (electrode EL3) in a plan view becomes larger, and consequently, the capacitance of the capacitor formed between the electrodes EL1 and EL2 (electrode EL3) becomes larger, further suppressing the superimposition of common mode noise on the signal transmitted between coil CL1 and coil CL2.

### Third Embodiment

The semiconductor device DEV3 according to the third embodiment will be described. Here, the differences from the semiconductor device DEV2 will be mainly described, and repetitive descriptions will not be repeated.

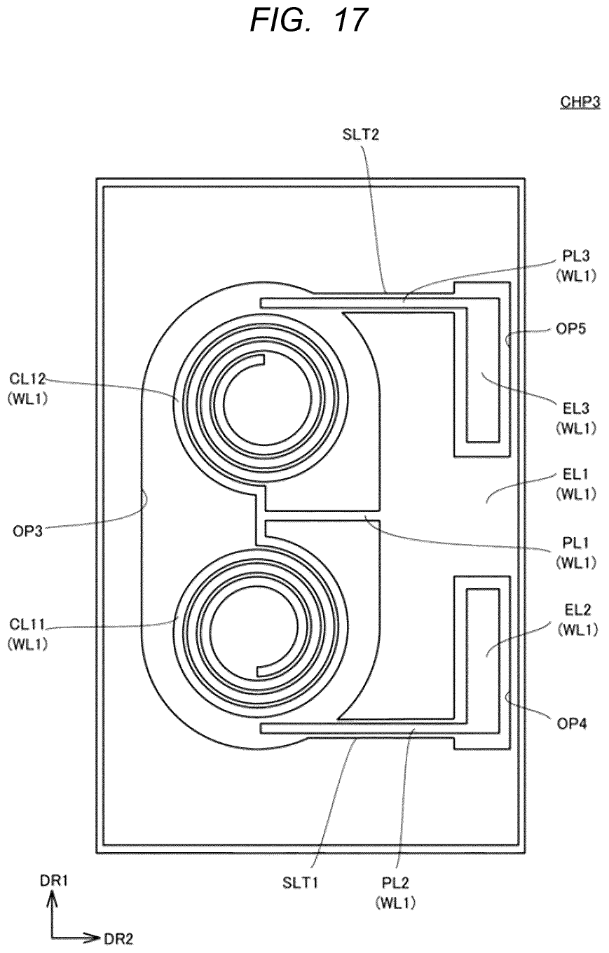

As shown in FIGS. 17, 18, 19, 20, and 21, in the semiconductor chip CHP3 of the semiconductor device DEV3, one of the adjacent two electrodes EL1 of the multiple wiring layers WL and the other of the adjacent two electrodes EL2 (electrode EL3) of the multiple wiring layers WL overlap each other in a region (third region) overlapping with the guard ring GR in a plan view, in addition to the first region and the second region.

As shown in FIG. 17, the electrode EL1 of the wiring layer WL1 overlaps with the guard ring GR in a plan view. The electrode EL1 of the wiring layer WL1 has opening portions OP3, OP4, OP5, and slits SLT1 and SLT2 formed therein.

The opening portion OP3 overlaps with opening portion OP1 in a plan view. The coil CL1 is located at an inside of the opening portion OP3 in a plan view. The opening portions OP4 and OP5 overlap with the pads PD5 and PD6, respectively, in a plan view. Electrodes EL2 and EL3 of the wiring layer WL1 are located at an inside of the opening portions OP4 and OP5, respectively, in a plan view. The slits SLT1 and SLT2 extend in the second direction DR2. The lead-out wire PL1 extends from the electrode EL2 through the slit SLT1 to the vicinity of the coil CL11, and the lead-out wire PL2 extends from the electrode EL3 through the slit SLT2 to the vicinity of the coil CL12.

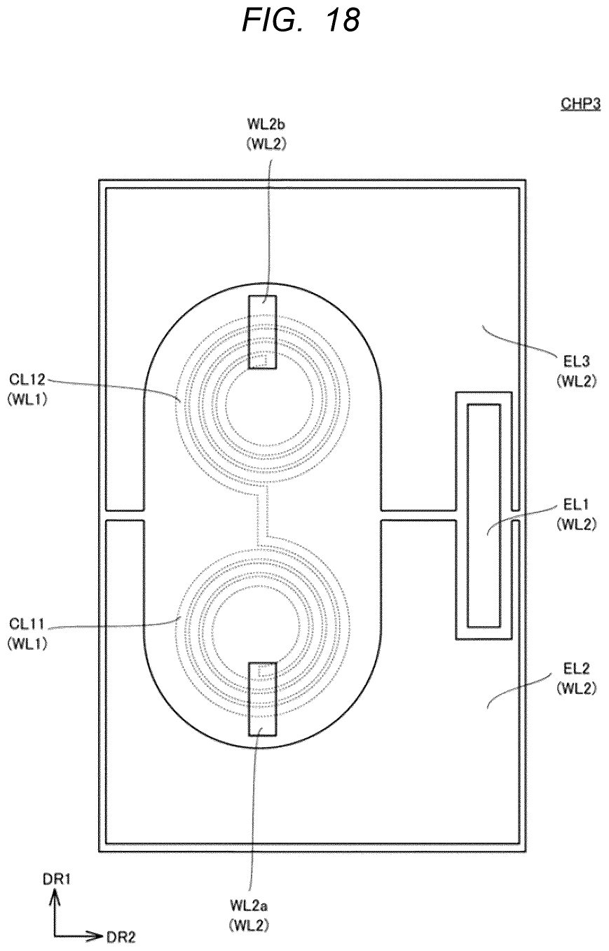

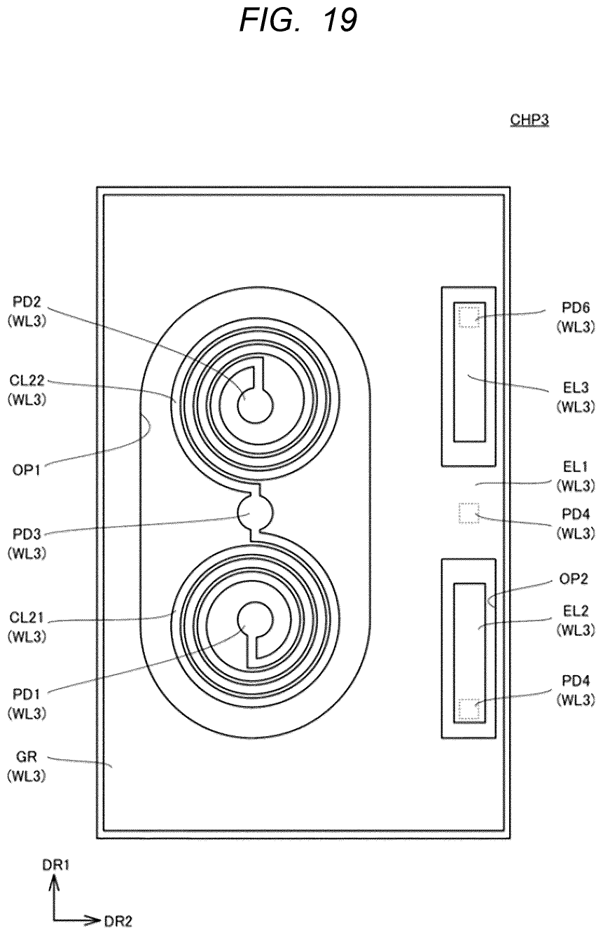

As shown in FIG. 18, the electrodes EL2 and EL3 of the wiring layer WL2 overlap with the guard ring GR in a plan view. The electrodes EL2 and EL3 of the wiring layer WL2 are separated from each other. The electrode EL1 of the wiring layer WL2 overlaps with the pad PD4 in a plan view. As shown in FIG. 19, the electrode EL1 of the wiring layer WL3, i.e., the pad PD4, is connected to the guard ring GR.

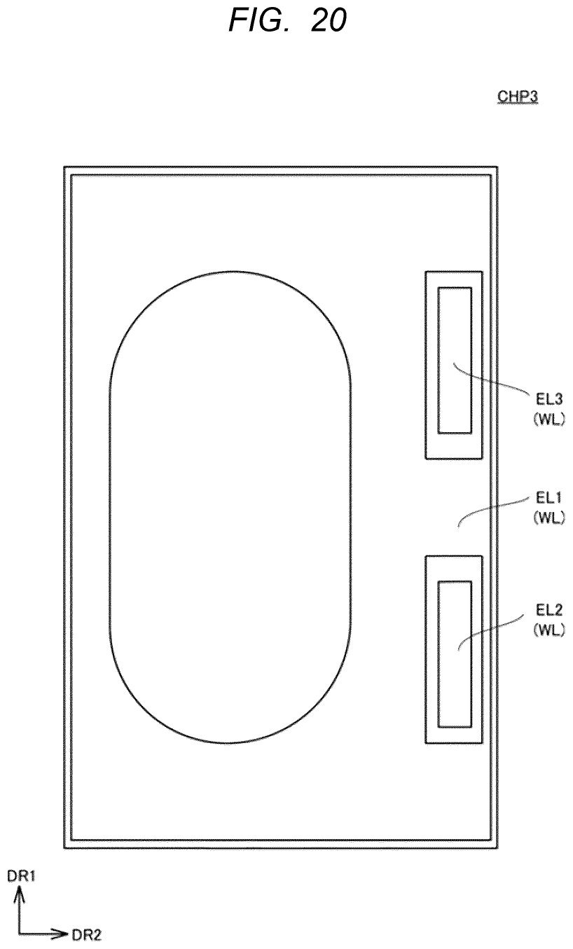

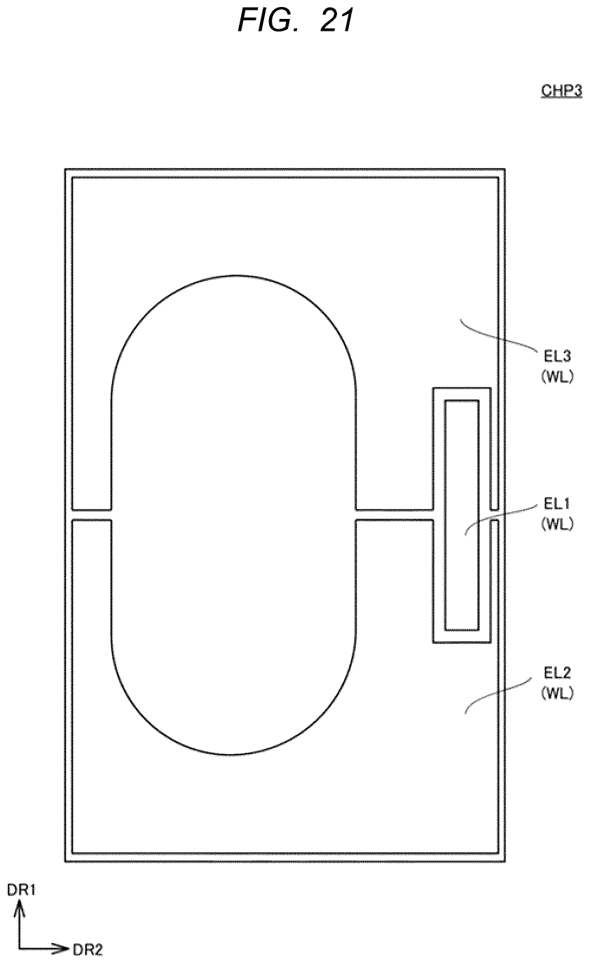

As shown in FIG. 20, one of the odd-numbered electrodes EL1 and EL2 counted from the lowermost of the multiple wiring layers WL has the same shape as the electrodes EL1 and EL2 of the wiring layer WL1. However, the odd-numbered electrode EL1 counted from the lowermost of the multiple wiring layers WL does not have slits SLT1 and SLT2 formed therein. As shown in FIG. 21, one of the even-numbered electrodes EL1 and EL2 counted from the lowermost of the multiple wiring layers WL has the same shape as the electrodes EL1 and EL2 of the wiring layer WL2. In this way, in the semiconductor chip CHP3 of the semiconductor device DEV3, one of the adjacent two electrodes EL1 of the multiple wiring layers WL and the other of the adjacent two electrodes EL2 (electrode EL3) of the multiple wiring layers WL overlap each other in a region (third region) overlapping with the guard ring GR in a plan view, in addition to the first region and the second region.

Thus, in the semiconductor chip CHP3 of the semiconductor device DEV3, one of the adjacent two electrodes EL1 of the multiple wiring layers WL and the other of the adjacent two electrodes EL2 (electrode EL3) of the multiple wiring layers WL overlap each other in the third region overlapping with the guard ring GR in a plan view, in addition to the first region and the second region. Therefore, in the semiconductor chip CHP3 of the semiconductor device DEV3, compared to the semiconductor chip CHP3 of the semiconductor device DEV2, the overlap between electrode EL1 and electrode EL2 (electrode EL3) in a plan view is larger, and consequently, the capacitance of the capacitor formed between electrode EL1 and electrode EL2 (electrode EL3) increases, further suppressing the superimposition of common mode noise on the signal transmitted between coil CL1 and coil CL2. If the chip size is set to 1.2 mm×1 mm, the distance between pad PD4 and pad PD5, as well as the distance between pad PD4 and pad PD5, is 100 μm, the distance between coil CL2 and opening portion OP1 is 150 μm, and the distance between the outer circumference of guard ring GR and the outer circumference of semiconductor chip CHP3 is 80 μm, a capacitance of approximately 240 pF can be obtained.

### Fourth Embodiment

The semiconductor device DEV3 according to the fourth embodiment will be described. Here, the differences from the semiconductor device DEV3 will be mainly explained, and repetitive descriptions will not be repeated.

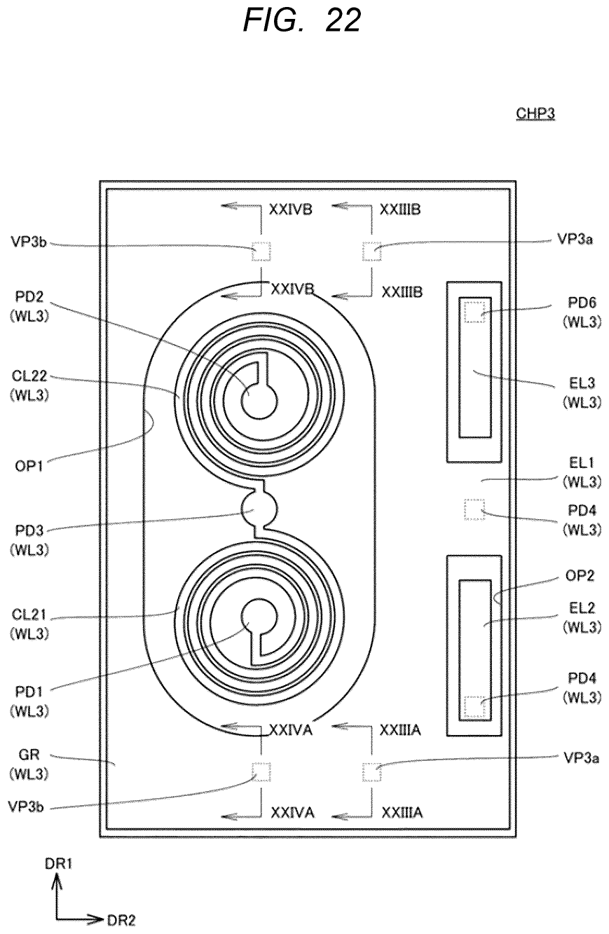

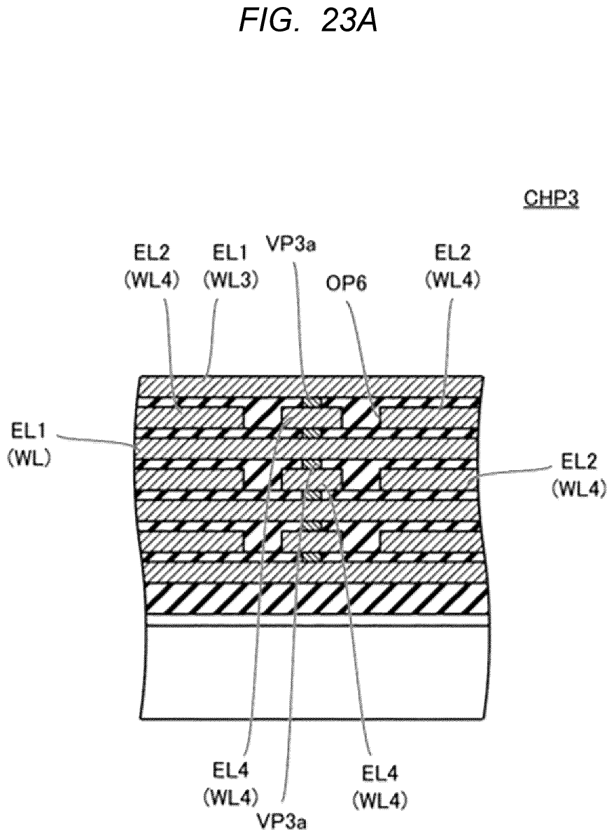

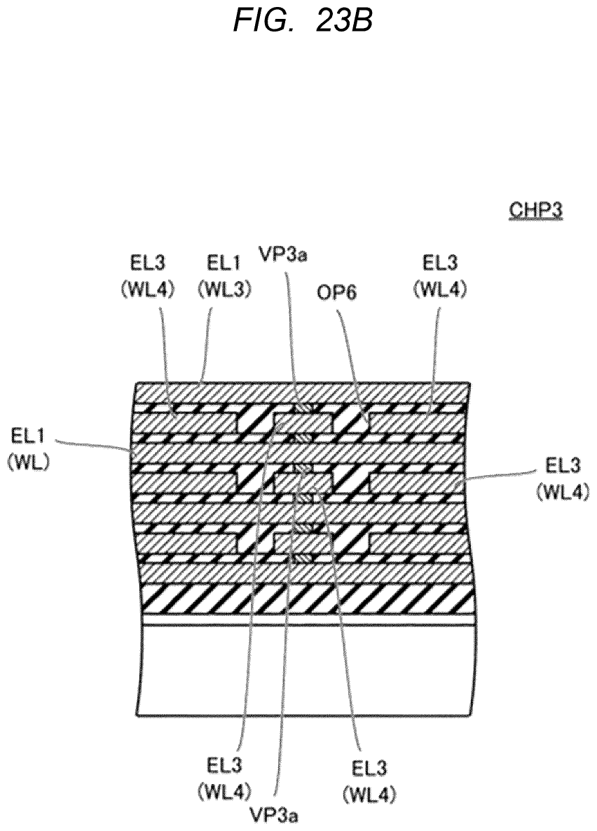

As shown in FIG. 22, FIG. 23A, and FIG. 23B, in the semiconductor chip CHP3 of the semiconductor device DEV4, each of the even-numbered wiring layers WL4, counted from the top layer among the multiple wiring layers WL, has a connection electrode EL4. However, if the wiring layer WL1 is located as an even-numbered layer from the top, the wiring layer WL1 does not have a connection electrode EL4. In each of the multiple wiring layers WL4, an opening portion OP6 is formed in electrode EL2 (electrode EL3). In each of the multiple wiring layers WL4, the connection electrode EL4 is located at an inside of the opening portion OP6. In other words, the connection electrode EL4 is electrically isolated from electrode EL2 (electrode EL3).

Each connection electrode EL4 of the multiple wiring layers WL4 overlaps with each other in a plan view. The semiconductor chip CHP3 of the semiconductor device DEV4 further includes multiple via plugs VP3a. In two adjacent wiring layers among the multiple wiring layers WL, the connection electrode EL4 is connected to electrode EL1 via the via plug VP3a.

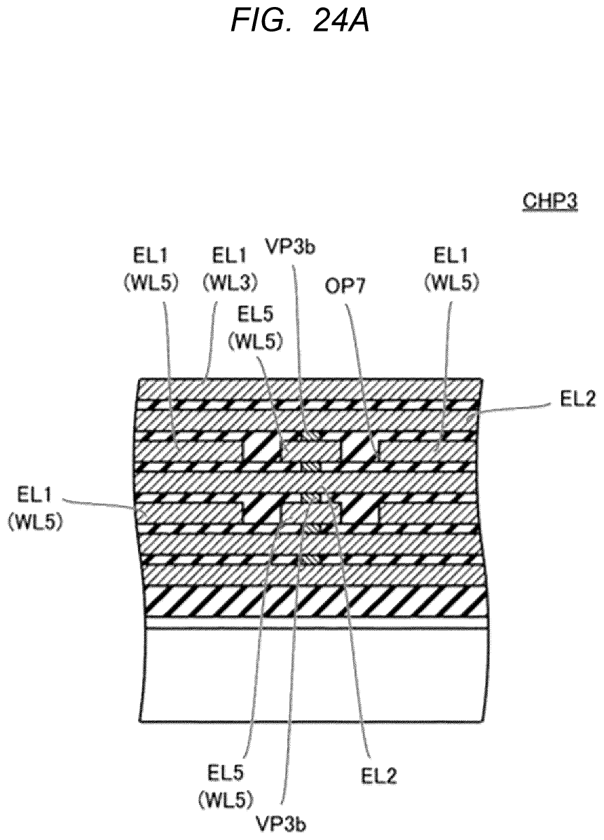

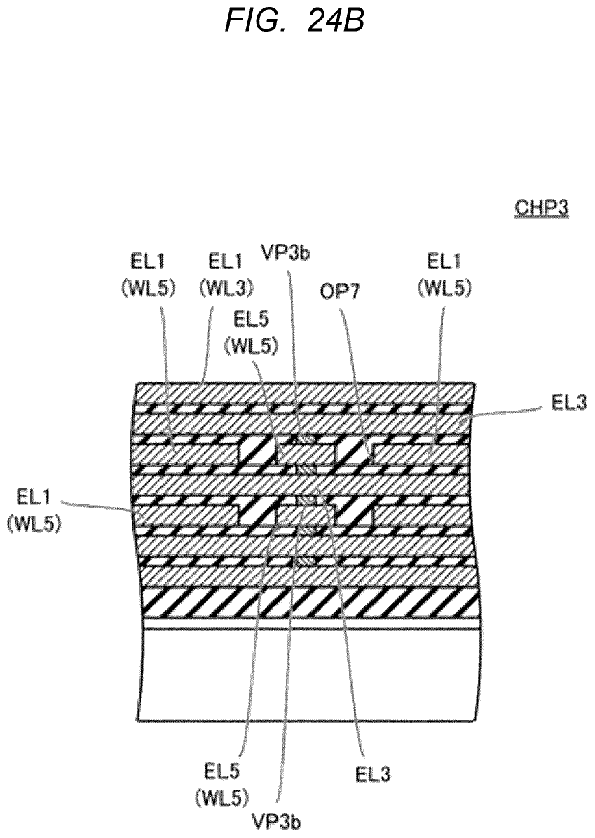

As shown in FIG. 22, FIG. 24A, and FIG. 24B, in the semiconductor chip CHP3 of the semiconductor device DEV4, each of the odd-numbered wiring layers WL5, counted from the top layer among the multiple wiring layers WL, has a connection electrode EL5. However, the wiring layer WL3 does not have a connection electrode EL5. Also, if the wiring layer WL1 is located as an odd-numbered layer from the top, the wiring layer WL1 does not have a connection electrode EL5. In each of the multiple wiring layers WL5, an opening portion OP7 is formed in electrode EL1. In each of the multiple wiring layers WL5, the connection electrode EL5 is located at an inside of the opening portion OP7. In other words, the connection electrode EL5 is electrically isolated from electrode EL1.

Each connection electrode EL5 of the multiple wiring layers WL5 overlaps with each other in a plan view. The semiconductor chip CHP3 of the semiconductor device DEV4 further includes multiple via plugs VP3b. In the two adjacent wiring layers among the multiple wiring layers WL, the connection electrode EL5 is connected to electrode EL2 (electrode EL3) via the via plug VP3b.

In the semiconductor chip CHP3 of the semiconductor device DEV4, the area between electrodes EL1 (electrodes EL2, EL3) to which the same potential is applied is connected by connection electrode EL4 and via plug VP3a (connection electrode EL5 and via plug VP3b). Therefore, according to the semiconductor chip CHP3 of the semiconductor device DEV4, the chip strength is enhanced, and consequently, warping is suppressed. In FIG. 22, only parts of the multiple via plugs VP3a and some of the via plugs VP3b are shown with dotted lines.

### First Modified Example

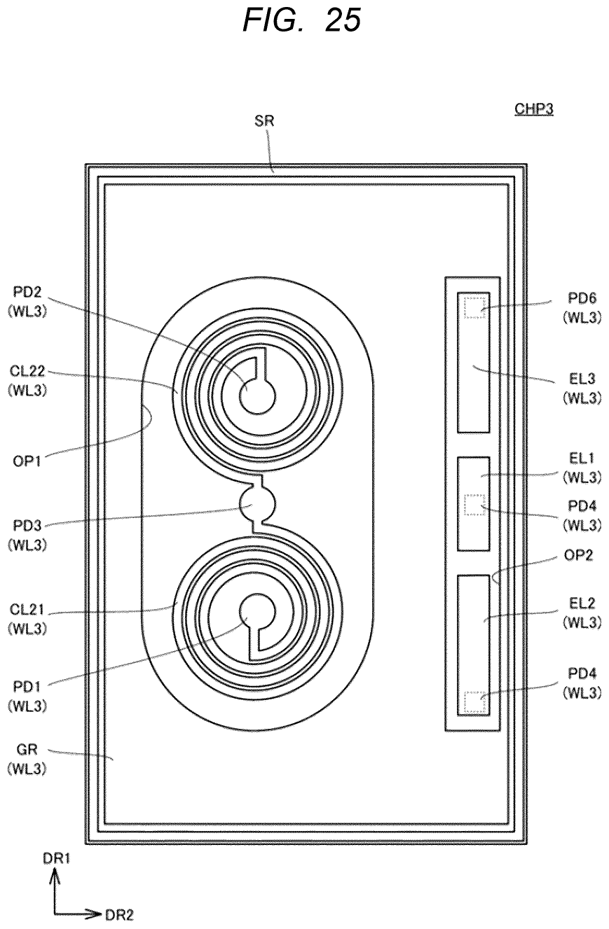

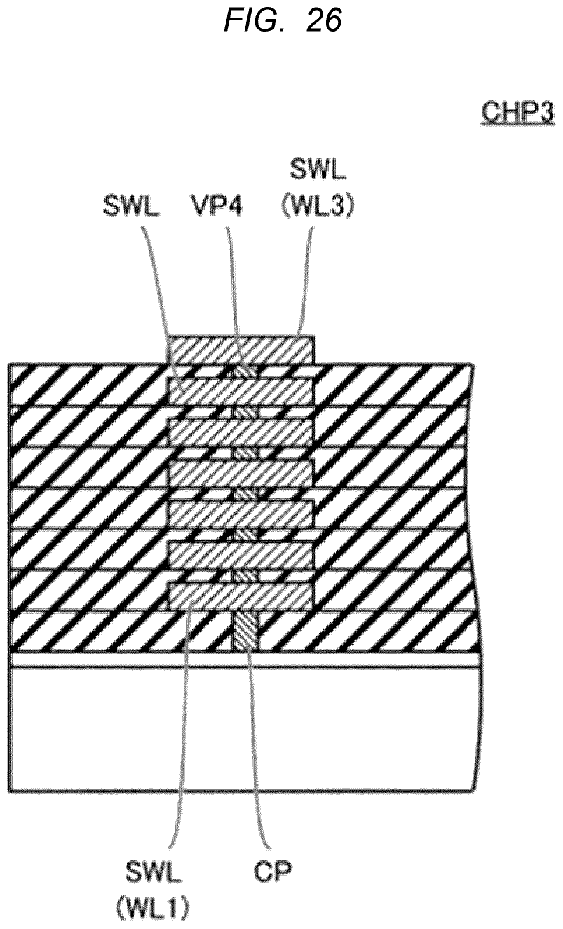

As shown in FIGS. 25 and 26, the semiconductor chip CHP3 of the semiconductor device DEV1 may further include a seal ring SR. The semiconductor chip CHP3 of the semiconductor device DEV2 to the semiconductor device DEV4 may also similarly include a seal ring SR. The seal ring SR is formed on the outer peripheral edge portion of the semiconductor substrate SUB in plan view. The guard ring GR is located at an inside of the seal ring SR in plan view. The seal ring SR includes multiple seal ring wiring SWL, multiple via plugs VP4, and a contact plug CP.

Each of the multiple wiring layers WL includes a seal ring wiring SWL. Additionally, the semiconductor chip CHP3 of the semiconductor device DEV1 to the semiconductor device DEV3 includes a contact plug CP and multiple via plugs VP4. Each seal ring wiring SWL of the multiple wiring layers WL overlaps in a plan view. The via plug VP4 is formed inside each of the multiple interlayers insulating films ILD. However, a contact plug CP is formed inside one of the lowermost interlayers insulating films ILD. The via plug VP4 connects two adjacent seal ring wiring SWL of the multiple wiring layers WL. The contact plug CP connects the seal ring wiring SWL of the wiring layer WL1 and the semiconductor substrate SUB.

### Second Modified Example

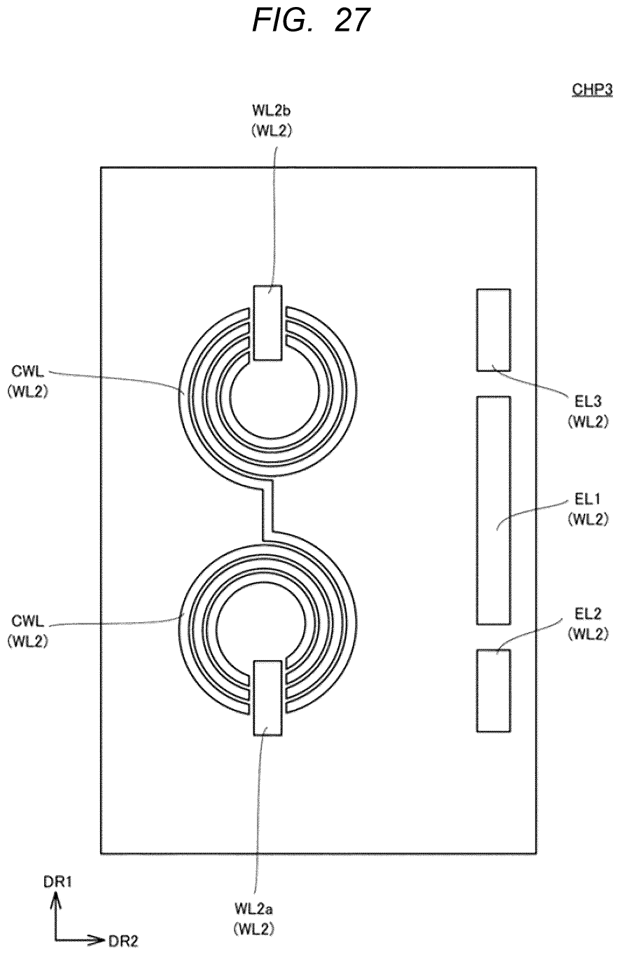

As shown in FIG. 27, the wiring layer WL2 in the semiconductor chip CHP3 of the semiconductor device DEV1 may further include a coil wiring CWL. The coil wiring CWL overlaps with the coil CL1 in a plan view. Although not shown, the coil wiring CWL is connected to the coil CL1 via a via plug. This reduces the electrical resistance of the coil CL1.

Although the invention made by the inventor has been specifically described based on the embodiment, the present invention is not limited to the above embodiment, and it is needless to say that various modifications can be made without departing from the gist thereof.

What is claimed is:

1. A semiconductor device comprising:
a semiconductor substrate having an upper surface; and
a plurality of wiring layers and a plurality of insulating layers alternately stacked on the upper surface of the semiconductor substrate,
wherein the plurality of insulating layers includes:
a first insulating layer located between a first wiring layer, which is located at a lowermost layer among the plurality of wiring layers in cross-sectional view, and the semiconductor substrate; and
a second insulating layer located between a second wiring layer, which is located at one layer above the first wiring layer among the plurality of wiring layers in cross-sectional view, and the first wiring layer,
wherein the first wiring layer includes:
a first coil;
a first lead-out wiring electrically connected to an outermost peripheral portion of the first coil; and
a second lead-out wiring electrically connected to an innermost peripheral portion of the first coil,
wherein a wiring layer, which is located above the first wiring layer among the plurality of wiring layers in cross-sectional view, has a second coil overlapping the first coil,
wherein each of the plurality of wiring layers includes:
a first electrode electrically connected to the first lead-out wiring; and
a second electrode electrically connected to the second lead-out wiring,
wherein the first electrode and the second electrode both provided in a third wiring layer, which is located at an uppermost layer among the plurality of wiring layers in cross-sectional view, form a first pad and a second pad, respectively, and
wherein the first electrode provided in one of two wiring layers, which are adjacent to each other, among the plurality of wiring layers and the second electrode provided in an other of the two wiring layers, which are adjacent to each other, among the plurality of wiring layers overlap each other.

2. The semiconductor device according to claim 1, wherein the first electrode provided in the one of the two wiring layers and the second electrode provided in the other of the two wiring layers overlap each other in a first region, which is located between the first pad and the second pad.

3. The semiconductor device according to claim 2,
wherein the third wiring layer, which is located at the uppermost layer among the plurality of wiring layers in cross-sectional view, further includes a guard ring surrounding the second coil in plan view,
wherein the guard ring has an opening portion, and
wherein the first pad and the second pad are located at an inside of the opening portion in plan view.

4. The semiconductor device according to claim 1,
wherein the third wiring layer, which is located at the uppermost layer among the plurality of wiring layers in cross-sectional view, further includes a guard ring surrounding the second coil in plan view,
wherein the guard ring has an opening portion,
wherein the first pad and the second pad are located at an inside of the opening portion in plan view, and
wherein the first electrode provided in one of the two wiring layers and the second electrode provided in the other of the two wiring layers overlap each other in a first region, which is located between the first pad and the second pad, and in a second region, which is located an inside of the opening portion and also an outside of the first region.

5. The semiconductor device according to claim 1,
wherein the third wiring layer, which is located at the uppermost layer among the plurality of wiring layers in cross-sectional view, further includes a guard ring surrounding the second coil in plan view,
wherein the guard ring has an opening portion, and
wherein the first electrode provided in one of the two wiring layers and the second electrode provided in the other of the two wiring layers overlap each other in a first region, which is located between the first pad and the second pad, in a second region, which is located an inside of the opening portion and also an outside of the first region, and in a third region, which is overlapping the guard ring.

6. The semiconductor device according to claim 5, further comprising:
a plurality of first via plugs,
wherein each of the plurality of wiring layers, which is located at an even-numbered layer from the uppermost layer among the plurality of wiring layers, has a first connection electrode, and
wherein, in the two wiring layers, one of the plurality of first via plugs connects the first connection electrode and the first electrode.

7. The semiconductor device according to claim 1, further comprising:
a seal ring located on an outer peripheral edge portion of the semiconductor substrate in plan view,
wherein the third wiring layer, which is located at the uppermost layer among the plurality of wiring layers in cross-sectional view, further includes a guard ring surrounding the second coil in plan view, and
wherein the guard ring is located at an inside of the seal ring in plan view.

8. The semiconductor device according to claim 1, wherein the second coil is provided in the third wiring layer, which is located at the uppermost layer among the plurality of wiring layers in cross-sectional view.
